(19) United States
(12) Patent Application Publication
(10) Pub. No.: US 2025/0379160 A1
(43) Pub. Date: Dec. 11, 2025

(54) ELECTRONIC DEVICE AND METHOD FOR MANUFACTURING THE SAME

(71) Applicant: Innolux Corporation, Miaoli County (TW)

(72) Inventors: Yu-Cheng Gong, Miaoli County (TW); Yung-Chieh Tseng, Miaoli County (TW); Te-Hsun Lin, Miaoli County (TW); Wen-Hsiang Liao, Miaoli County (TW); Ker-Yih Kao, Miaoli County (TW)

(73) Assignee: Innolux Corporation, Miaoli County (TW)

(21) Appl. No.: 19/212,718

(22) Filed: May 20, 2025

Related U.S. Application Data
(60) Provisional application No. 63/658,446, filed on Jun. 11, 2024.

(30) Foreign Application Priority Data
Sep. 27, 2024 (CN) 202411361626.5

(51) Int. Cl. H01L 23/00; H01L 21/48; H01L 21/56; H01L 23/31; H01L 23/367; H01L 23/498; H01L 23/538

(52) U.S. Cl. CPC H01L 23/562; H01L 21/4857; H01L 21/4882; H01L 21/565; H01L 21/568; H01L 23/3128; H01L 23/3135; H01L 23/3675; H01L 23/49816; H01L 23/5383; H01L 23/5389; H01L 24/19; H01L 24/20; H01L 2224/214; H01L 2924/3511

(57) ABSTRACT

An electronic device and a method for manufacturing the same are provided. The electronic device includes an electronic unit, an encapsulation layer, a circuit structure, and a first heat-conducting assembly is provided. The encapsulation layer surrounds the electronic unit and has a first side and a second side opposite to each other. The circuit structure is disposed on the first side of the encapsulation layer and is electrically connected to the electronic unit. The first heat-conducting assembly is disposed on the second side of the encapsulation layer. Viewing in a top view, the first heat-conducting assembly has a first area, the electronic unit has a second area, and a ratio of the first area to the second area is greater than or equal to 1 and less than 9.8.

### CROSS-REFERENCE TO RELATED APPLICATION

This application claims the priority benefit of U.S. provisional application Ser. No. 63/658,446, filed on Jun. 11, 2024 and China application serial no. 202411361626.5, filed on Sep. 27, 2024. The entirety of each of the above-mentioned patent applications is hereby incorporated by reference herein and made a part of this specification.

### BACKGROUND

### Technical Field

The disclosure relates to an electronic device and a method for manufacturing the same, and particularly relates to an electronic device capable of improving a heat dissipation effect and a method for manufacturing the same.

### Description of Related Art

Electronic devices or semiconductor devices may be formed through a panel-level package (PLP) process or a wafer-level package (WLP) process. As requirements on heat dissipation of the electronic devices or the semiconductor devices increase, changes in designs of the electronic devices or the semiconductor devices may be accompanied by generation of warpage during a manufacturing process, which in turn leads to poor reliability of the produced electronic devices. How to improve a heat dissipation effect to reduce or avoid generation of warpage has become one of the problems that need to be solved urgently.

### SUMMARY

The disclosure is directed to an electronic device, which is adapted to improve a heat dissipation effect.

The disclosure is directed to a method for manufacturing an electronic device, which is used to manufacture the above-mentioned electronic device.

According to an embodiment of the disclosure, the electronic device includes an electronic unit, an encapsulation layer, a circuit structure, and a first heat-conducting assembly. The encapsulation layer surrounds the electronic unit and has a first side and a second side opposite to each other. The circuit structure is disposed on the first side of the encapsulation layer and is electrically connected to the electronic unit. The first heat-conducting assembly is disposed on the second side of the encapsulation layer. Viewing in a top view, the first heat-conducting assembly has a first area, the electronic unit has a second area, and a ratio of the first area to the second area is greater than or equal to 1 and less than 9.8.

According to an embodiment of the disclosure, a method for manufacturing an electronic device includes following steps. An electronic unit is provided on a carrier. An encapsulation layer is formed on the carrier, wherein the encapsulation layer surrounds the electronic unit and has a first side and a second side opposite to each other, and the first side is located on the carrier. A first heat-conducting assembly is provided on the second side of the encapsulation layer. The carrier is removed to expose the first side of the encapsulation layer. A circuit structure is formed on the first side of the encapsulation layer, wherein the circuit structure is electrically connected to the electronic unit. Viewing in a top view, the first heat-conducting assembly has a first area, the electronic unit has a second area, and a ratio of the first area to the second area is greater than or equal to 1 and less than 9.8.

Based on the above descriptions, in the embodiments of the disclosure, the ratio of the first area of the first heat-conducting assembly to the second area of the electronic unit is greater than or equal to 1 and less than 9.8, thereby improving the heat dissipation effect of the electronic device of the disclosure, and reducing or preventing warpage of the electronic device.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic cross-sectional view of an electronic device according to an embodiment of the disclosure.

FIG. 1B is a schematic top view of the electronic device of FIG. 1A.

FIG. 2 to FIG. 12 are schematic cross-sectional views of various electronic devices according to various embodiments of the disclosure.

FIG. 13A to FIG. 13E are schematic cross-sectional views of a method for manufacturing an electronic device according to an embodiment of the disclosure.

FIG. 14A to FIG. 14B are schematic cross-sectional views of partial steps of a method for manufacturing an electronic device according to another embodiment of the disclosure.

### DESCRIPTION OF THE EMBODIMENTS

The disclosure may be understood by referring to the following detailed description in collaboration with the accompanying drawings. It should be noted that in order to facilitate understanding for the readers and for the simplicity of the drawings, the multiple drawings in the disclosure only depict a part of the electronic device, and specific elements in the drawings are not drawn according to actual scales. In addition, the number and size of each element in the drawings are only for illustration and are not intended to limit the scope of the disclosure.

Certain terms are used throughout the specification of the disclosure and the appended claims to refer to specific elements. Those skilled in the art should understand that electronic device manufacturers may probably use different names to refer to the same elements. This specification is not intended to distinguish between elements that have the same function but different names.

In the following specification and claims, the terms “containing”, “including”, etc., are open terms, so that they should be interpreted as meaning of “including but not limited to . . . ”.

In addition, relative terms such as “below” or “bottom” and “above” or “top” may be used in the embodiments to describe a relative relationship between one element and another element in the diagram. It is understood that if a device in the diagram is turned upside down, the element described as being on a “lower” side will become the element on the “upper” side.

In some embodiments of the disclosure, terms such as “connection”, “interconnection”, etc., unless otherwise defined, may refer to two structures being in direct contact, or may also refer to two structures not being in direct (indirect) contact, and there are other structures disposed between the two structures. Furthermore, these terms related to bonding or connecting may also include situations that both structures are movable, or both structures are fixed. In addition, the term “couple” includes energy transfer between two structures by means of direct or indirect electrical connection, or energy transfer between two separate structures by means of mutual induction.

It should be understood that when an element or film layer is referred to as being “on” or “connected” to another element or film layer, the element or film layer may be directly on the other element or film layer, or directly connected to the other element or film layer, or there is an intervening element or film layer there between (an indirect situation). Conversely, when an element or film layer is referred to be “directly” on or “directly connected” to another element or film layer, there is no intervening element or film layer there between.

In some embodiments of the disclosure, “adjacent” may refer to, for example, two structures overlapping each other in an extending direction of the electronic device or in a direction perpendicular to the extending direction of the electronic device. In some embodiments, there are no other components between the two structures, and in some embodiments, it may also refer to that there are other structures disposed between the two structures.

The terms “about,” “equal,” “equivalent,” or “same,” “substantially,” or “approximately” are generally interpreted as within 20% of a given value or range, or within 10%, 5%, 3%, 2%, 1% or 0.5% of a given value or range.

In the disclosure, an area, width, thickness or height of each component, or a distance or spacing between the components may be measured by using an optical microscope (OM), a scanning electron microscope (SEM), an α-step, an ellipsometer, or other suitable methods. In detail, according to some embodiments, a scanning electron microscope may be used to obtain a cross-sectional structural image of the components to be measured, and to measure an area, width, thickness or height of each component, or a distance or spacing between the components.

As used herein, terms “film” and/or “layer” may refer to any continuous or discontinuous structure and material (such as a material deposited by the method disclosed herein). For example, the film and/or layer may include two-dimensional materials, three-dimensional materials, nanoparticles, or even partial or complete molecular layer, or partial or complete atomic layer, or clusters of atoms and/or molecules. The film or layer may include a material or layer having pinholes, which may be at least partially continuous.

Although the terms, first, second, third, etc., may be used to describe a variety of components, the components are not limited to these terms. These terms are only used to distinguish a single component from other components in the specification. The claims may not use the same terms, which may be replaced by first, second, third, etc. according to an order in which the components are declared in the claims. Therefore, in the following description, a first component may be a second component in the claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should be noted that a term “roughness” used in the specification refers to a degree of undulations on a surface of an object. Specifically, a value of the “roughness” of a surface or sidewall may be obtained based on a ten-point average roughness (R_{Z}), where the ten-point average roughness (R_{Z}) is defined as taking five peak values and five trough values within an evaluation length, and calculating a sum of an absolute average of the five peak values and an absolute average of the five trough values. In detail, the ten-point average roughness (R_{Z}) is calculated according to a following equation:

$${R}_{z} = \frac{1}{5} {\sum }_{i = 1}^{5} {R}_{pi -} {R}_{vi}$$

Where, Rₚᵢ and Rᵥᵢ are respectively an i-th peak value and an i-th trough value. In some embodiments, the term “roughness” used herein refers to average roughness. Roughness may be measured by using common instruments in the technical field to which the disclosure belongs. For example, the average roughness of the surface may be measured by using a focus ion beam (FIB) microscope with a magnification of 5,000 to 50,000, a scanning electron microscopy (SEM), a transmission electron microscopy (TEM), or an atomic force microscopy (AFM) with a measurement scale from 10 μm to 100 μm.

It should be noted that the following embodiments may replace, reorganize, or mix technical features in several different embodiments to implement other embodiments without departing from the spirit of the disclosure.

The electronic device disclosed herein may include a power module, a semiconductor device, a semiconductor packaging device, a display device, an antenna device, a sensing device, a light-emitting device, or a splicing device, but the disclosure is not limited thereto. The electronic device may include a bendable or flexible electronic device. The electronic device may include electronic components. The electronic components may include passive components, active components, or a combination thereof, such as capacitors, resistors, inductors, variable capacitors, filters, diodes, transistors, sensors, micro-electromechanical system components (MEMS), liquid crystal chips, etc., but the disclosure is not limited thereto. The diode may include a light-emitting diode or a non-light emitting diode. The diode includes a P-N junction diode, a PIN diode, or a constant current diode. The light-emitting diode may include, for example, an organic light-emitting diode (OLED), a mini LED, a micro LED, a quantum dot LED, fluorescence, phosphor, or other suitable materials, or a combination thereof, but the disclosure is not limited thereto. The sensors may include, for example, capacitive sensors, optical sensors, electromagnetic sensors, fingerprint sensors (FPS), touch sensors, antennas, or pen sensors, etc., but the disclosure is not limited thereto. In the following description, a display device is used as an electronic device to illustrate the disclosure, but the disclosure is not limited thereto. According to the embodiments of the disclosure, a method for manufacturing the electronic device may be applied, for example, to a wafer-level package (WLP) process or a panel-level package (PLP) process, and may adopt a chip first process or a chip last/RDL first process, which will be further described in detail below. The electronic device referred to in the disclosure may include a system on package (SoC), a system in package (SiP), an antenna in package (AiP), co-packaged optical (CPO) or a combination thereof, but the disclosure is not limited thereto.

Reference will now be made in detail to exemplary embodiments of the disclosure, examples of which are illustrated in the accompanying drawings. Whenever possible, the same reference numerals are used in the drawings and the description to refer to the same or like parts.

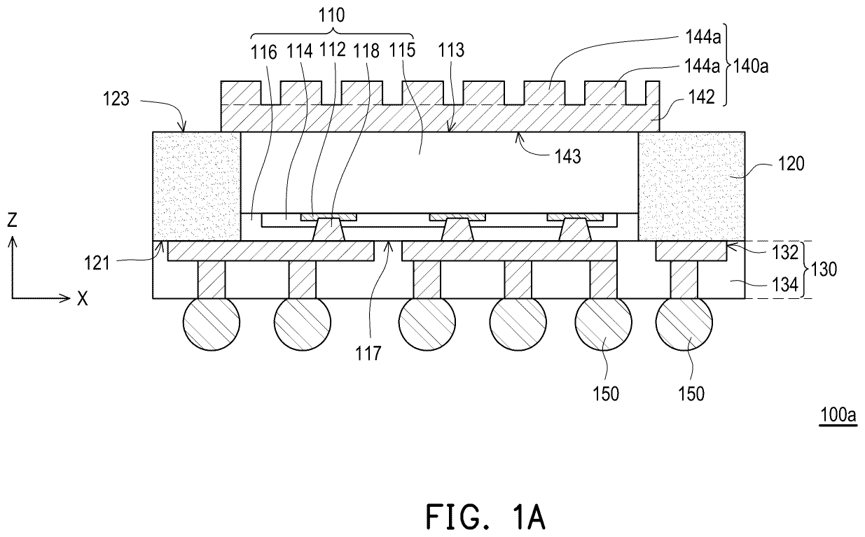

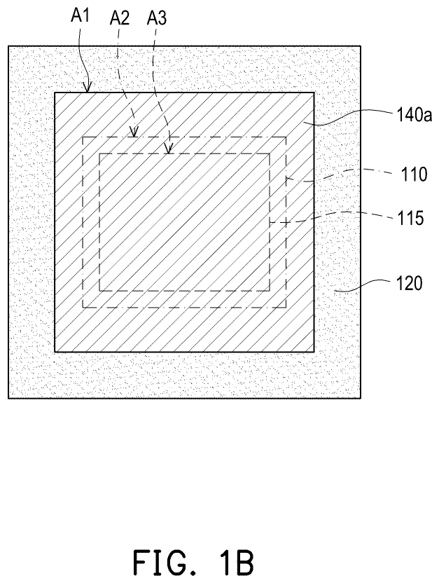

FIG. 1A is a schematic cross-sectional view of an electronic device according to an embodiment of the disclosure. FIG. 1B is a schematic top view of the electronic device of FIG. 1A. Referring to FIG. 1A and FIG. 1B simultaneously, in the embodiment, an electronic device 100a includes an electronic unit 110, an encapsulation layer 120, a circuit structure 130, and a first heat-conducting assembly 140a. The encapsulation layer 120 surrounds the electronic unit 110 and has a first side 121 and a second side 123 opposite to each other. The circuit structure 130 is disposed on the first side 121 of the encapsulation layer 120 and is electrically connected to the electronic unit 110. The first heat-conducting assembly 140a is disposed on the second side 123 of the encapsulation layer 120. Viewing in a top view, the first heat-conducting assembly 140a has a first area A1, and the electronic unit 110 has a second area A2, and a ratio of the first area A1 to the second area A2 is, for example, greater than or equal to 1 and less than 9.8 (1≤the first area A1/the second area A2<9.8). In an embodiment, the ratio of the first area A1 to the second area A2 is, for example, greater than or equal to 2 and less than 8 (2≤the first area A1/the second area A2<8). In detail, the first area A1 may be a specific surface area of the first heat-conducting assembly 140a. The area and the specific surface area may be measured through a microscope.

In an embodiment, the electronic unit 110 may be, for example, a known good die (KGD), a diode, an antenna unit, a sensor, a structure produced by a semiconductor-related process, or a structure produced by a semiconductor-related process disposed on a substrate (including polyimide, glass, silicon, or other suitable substrate materials), but the disclosure is not limited thereto.

Referring to FIG. 1A, in the embodiment, the electronic unit 110 may include a chip 115, a pad 112, a passivation layer 114, an insulating layer 116, and a metal column 118. In an embodiment, the chip 115 includes active components and passive components formed therein, but the disclosure is not limited thereto. The pad 112 is disposed on the chip 115 and may be electrically connected to other conductive components. A material of the pad 112 may be, for example, aluminum, copper, nickel, molybdenum, titanium, alloys or combinations of the above materials, or other suitable metal materials, but the disclosure is not limited thereto. The passivation layer 114 is formed on the chip 115 and has a contact opening that exposes a portion of the pad 112. The passivation layer 114 may be a dielectric layer formed of, for example, a silicon oxide layer, a silicon nitride layer, a silicon oxynitride layer, or other suitable dielectric materials, but the disclosure is not limited thereto. The insulating layer 116 is formed on the passivation layer 114, and a contact opening of the insulating layer 116 partially exposes the pad 112. The insulating layer 116 may be a dielectric layer formed of, for example, a polyimide layer or other suitable polymers, but the disclosure is not limited thereto. The metal column 118 is formed on the pad 112, and may be approximately aligned with a surface of the insulating layer 116, where a material of the metal column 118 may be, for example, copper, but the disclosure is not limited thereto. In an embodiment, a part of the metal column 118 may be embedded in the pad 112, where an embedded depth is, for example, 1 μm to 10 μm, but the disclosure is not limited thereto.

After the electronic unit 110 is manufactured, a cutting process is performed for cutting the electronic unit 110 into a plurality of electronic units 110. Due to the manufacturing process or other factors, sizes of a front surface and a back surface of the cut electronic unit 110 may be slightly different. In other words, orthogonal projection areas of a back surface 113 and an active surface 117 of the electronic unit 110 on a plane may be slightly different. In an embodiment, referring to FIG. 1B again, the electronic unit 110 includes a chip 115. Viewing in a top view, the chip 115 has a third area A3, and a ratio of the first area A1 to the third area A3 is greater than or equal to 1 and less than 9.8. The second area A2 of the electronic unit 110 is substantially the orthogonal projection area of the back surface 113, and the third area A3 of the chip 115 is substantially the orthogonal projection area of the active surface 117. In an embodiment, the first area A1 of the first heat-conducting assembly 140a is larger than the second area A2 of the electronic unit 110, and the second area A2 of the electronic unit 110 is larger than the third area A3 of the chip 115, but the disclosure is not limited thereto.

In a simulation experiment, a power of the electronic device 100a may be, for example, 1 W, 3 W, or 5 W. After the first heat-conducting assembly 140a is disposed on the back surface 113 of the electronic unit 110 of the electronic device 100a, when the first area A1 of the first heat-conducting assembly 140a is greater than or equal to the second area A2 of the electronic unit 110, a temperature of the electronic device 100a is significantly reduced, which improves the heat dissipation efficiency of the electronic device 100a. On the other hand, when the first area A1 of the first heat-conducting assembly 140a is less than 9.8 times of the second area A2 of the electronic unit 110, the risk of warpage may be reduced.

Since the first area A1 of the first heat-conducting assembly 140a is larger than the second area A2 of the electronic unit 110, where the ratio of the first area A1 to the second area A2 is greater than or equal to 1 and less than 9.8. Under this ratio, the electronic device 100a of the embodiment may have a better heat dissipation effect. Since the heat dissipation efficiency of the electronic device 100a of the embodiment is improved, warpage of the electronic device 100a may be reduced or avoided to achieve better structural reliability.

Further, referring to FIG. 1A, in the embodiment, the first heat-conducting assembly 140a may include a first portion 142 and a plurality of second portions 144a, where the first portion 142 is located between the electronic unit 110 and the plurality of second portions 144a, and the plurality of second portions 144a are connected to the first portion 142. In some embodiments, in a normal direction of the chip 115, the first portion of first heat-conducting assembly 140a, 140b, 140n, or 140p has a first height, the second portions of the first heat-conducting assembly 140a, 140b, 140n, or 140p have a second height, and the first height is greater than the second height.

The first portion of the first heat-conducting assembly 140a, 140b, 140n, or 140p has a first specific surface area, and the second portion of the first heat-conducting assembly 140a, 140b, 140n, or 140p has a second specific surface area. In some embodiments, a ratio of the second specific surface area to the first specific surface area is 1 to 8 (1≤the second specific surface area/the first specific surface area≤8). In some embodiments, the ratio of the second specific surface area to the first specific surface area is 1.5 to 5 (1.5≤the second specific surface area/the first specific surface area≤5), so that the electronic device 100 has good heat dissipation performance. In an embodiment, the first portion 142 may extend along a direction X, and the second portions 144a are separated from each other and may extend along a direction Z. In an embodiment, in the direction Z, a height of the first portion 142 may be greater than a height of the second portions 144a, but the disclosure is not limited thereto. In an embodiment, viewing in a cross-sectional view, a shape of the second portion 144a may be, for example, rectangular, but the disclosure is not limited thereto. In an embodiment, the first portion 142 has a surface 143 having a first surface area, and the second portions 144a have a second surface area. A ratio of the second surface area to the first surface area is, for example, between 1.5 and 5, which may achieve a better heat dissipation effect. The surface areas and the specific surface areas may be obtained through deduction and calculation after, for example, obtaining a top view and a cross-sectional view of a position to be measured through a microscope.

As shown in FIG. 1A, the first portion 142 of the first heat-conducting assembly 140a of the embodiment may directly contact the back surface 113 of the electronic unit 110, so that heat generated by the electronic unit 110 may be directly transferred to the outside through the first heat-conducting assembly 140a. In an embodiment, an exterior surface of the first portion 142 and exterior surfaces of the second portions 144a are all exposed to the outside so as to achieve a better heat dissipation effect. In an embodiment, the first portion 142 may be a heat dissipation substrate, and the second portions 144a may be heat dissipation fins, which may increase a heat dissipation area to improve the heat dissipation effect. In an embodiment, a material of the first heat-conducting assembly 140a may be copper or aluminum, but the disclosure is not limited thereto.

Furthermore, in an embodiment, the encapsulation layer 120 surrounds the electronic unit 110. In the embodiment, “one component surrounds another component” may mean that the component may at least partially contact a side surface of the another component in the cross-sectional view of the electronic device 100a. As shown in FIG. 1A, the encapsulation layer 120 may directly contact a side surface of the electronic unit 110. The encapsulation layer 120 may provide the electronic unit 110 with a moisture-proof effect, thereby improving reliability of the electronic device 100a. In an embodiment, a material of the encapsulation layer 120 is, for example, a polymer or epoxy molding compound (EMC), where the encapsulation layer 120 is, for example, formed by a molding process, but the disclosure is not limited thereto. In an embodiment, the back surface 113 of the electronic unit 110 may be aligned with the second side 123 of the encapsulation layer 120, but the disclosure is not limited thereto. In an embodiment, the first heat-conducting assembly 140a not only directly contacts the back surface 113 of the electronic unit 110, but also extends to contact a part of the encapsulation layer 120.

In addition, the circuit structure 130 of the embodiment may include any suitable structure formed by stacking a conductive layer 132 and an insulating layer 134, where a stacking direction of the insulating layer 134 and the conductive layer 132 may be along the direction Z. In an embodiment, the circuit structure 130 may directly contact the first side of the encapsulation layer 120, where the metal column 118 of the electronic unit 110 directly contacts the conductive layer 132 of the circuit structure 130 for electrically connecting the circuit structure 130. In an embodiment, a material of the conductive layer 132 may be, for example, copper, titanium, nickel, or a combination or alloy of the above materials, but the disclosure is not limited thereto. In an embodiment, a material of the insulating layer 134 may be, for example, a build-up film, polyimide, epoxy, silicon dioxide, silicon nitride, solder resist, or a combination of the above materials, but the disclosure is not limited thereto.

In an embodiment, the circuit structure 130 may also be referred to as a redistribution layer. The redistribution layer may be electrically connected to a chip or other electronic components through solder balls or other bonding components. The redistribution layer may include at least one dielectric layer and at least one conductive layer alternately stacked along the direction Z. Through the at least one dielectric layer and the at least one conductive layer, route may be redistributed and/or the fan-out or fan-in areas thereof may be increased, or different electronic components may be electrically connected to each other through the redistribution layer. For example, a pitch between two adjacent contact pads at one end of the redistribution layer contacting the electronic component may be less than or equal to a pitch between two adjacent contact pads at the other end of the redistribution layer away from the electronic component. Therefore, the redistribution layer may adjust a route fan-out situation or electrically connect a circuit structure/electronic component with a first pitch to a circuit structure/electronic component with a second pitch, but the disclosure is not limited thereto. A method of forming the redistribution layer may include forming at least one dielectric layer and at least one conductive layer by using a lithography process, a surface treatment process, a laser process, an electroplating process, a deposition process or other processes. The surface treatment process includes roughening or activating a surface of a dielectric layer or a conductive layer to improve its bonding ability, for example, a bonding force with a subsequent film layer is improved by increasing the surface roughness.

In addition, the electronic device 100a of the embodiment further includes a connecting member 150, which is disposed on the circuit structure 130 and is electrically connected to the circuit structure 130. The electronic device 100a may be electrically connected to an external circuit through the connecting member 150. In an embodiment, the connecting member 150 may be made of, for example, tin, nickel, gold, silver, palladium, copper, gallium, alloys thereof, or combinations thereof, but the disclosure is not limited thereto. In an embodiment, the connecting member 150 may be, for example, a solder ball, but the disclosure is not limited thereto.

It should be noted that the following embodiments use the component referential numbers and some contents of the previous embodiments, wherein the same referential number is used to represent the same or similar components, and the description of the same technical content is omitted. The description of the omitted parts may be referred to the previous embodiments, which will not be repeated in the following embodiments.

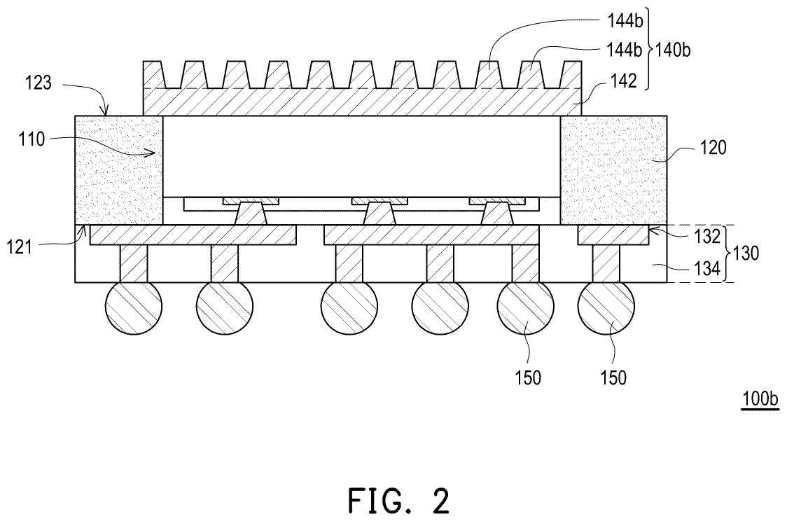

FIG. 2 to FIG. 12 are schematic cross-sectional views of various electronic devices according to various embodiments of the disclosure.

Referring to FIG. 1A and FIG. 2 at the same time, an electronic device 100b of the embodiment is similar to the electronic device 100a of FIG. 1A, and a difference therebetween is that in the embodiment, a first heat-conducting assembly 140b includes a first portion 142 and a plurality of second portions 144b, where viewing in a cross-sectional view, a shape of the second portion 144b is a trapezoid, but the disclosure is not limited thereto. In an embodiment, viewing in the cross-sectional view, the shape of the second portion 144b may also be a triangle or a square. In short, the cross-sectional shape of the second portion 144b may be a square, a rectangle, a trapezoid, a triangle, a semicircle, an ellipse, an arc, or a combination of the above shapes, which may increase a heat dissipation surface area.

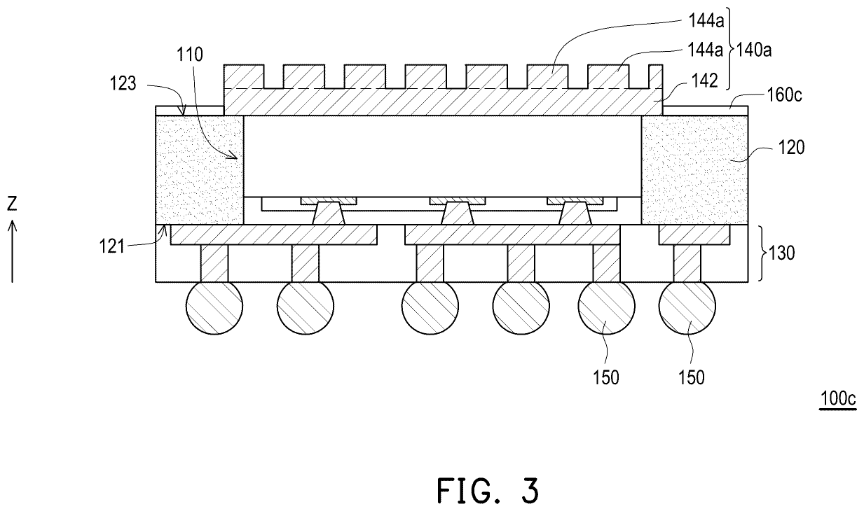

Referring to FIG. 1A and FIG. 3 at the same time, an electronic device 100c of the embodiment is similar to the electronic device 100a of FIG. 1A, and a difference therebetween is that in the embodiment, the electronic device 100c further includes a buffer layer 160c disposed on the second side 123 of the encapsulation layer 120 and surrounding the first heat-conducting assembly 140a. In the embodiment, the buffer layer 160c directly contacts the second side 123 of the encapsulation layer 120 and a part of a sidewall of the first portion 142 of the first heat-conducting assembly 140a. In the direction Z, a height of the buffer layer 160c is lower than a height of the first heat-conducting assembly 140a, that is, the buffer layer 160c exposes a part of a side surface of the first heat-conducting assembly 140a, but the disclosure is not limited thereto. In an embodiment, a ratio of an area of the buffer layer 160c to an area of the encapsulation layer 120 is between 0.1 and 0.9 (0.1≤the area of the buffer layer 160c/the area of the encapsulation layer 120≤0.9). In some embodiments, the ratio of the area of the buffer layer 160c to the area of the encapsulation layer 120 is between 0.3 and 0.7 (0.3≤the area of the buffer layer 160c/the area of the encapsulation layer 120≤0.7), but the disclosure is not limited thereto. In an embodiment, a material of the buffer layer 160c is, for example, an organic material or an inorganic material, but the disclosure is not limited thereto.

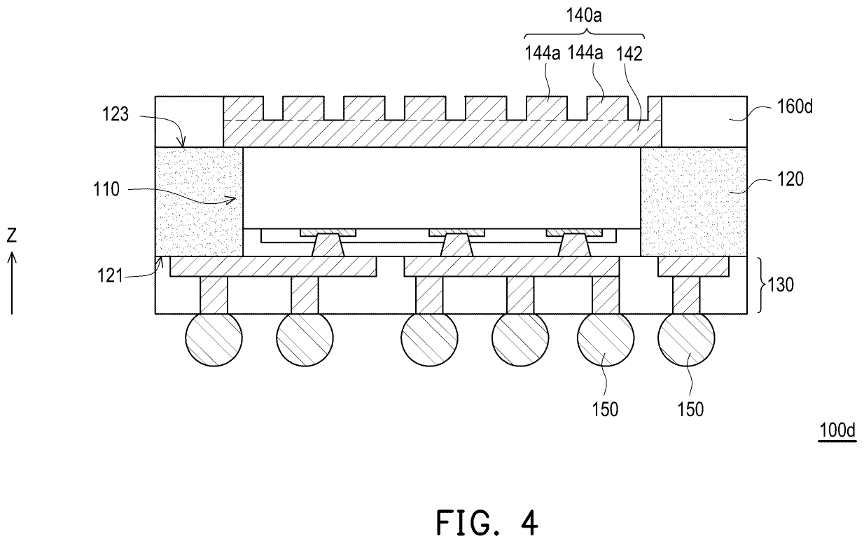

Referring to FIG. 3 and FIG. 4 at the same time, an electronic device 100d of the embodiment is similar to the electronic device 100c of FIG. 3, and a difference therebetween is that in the embodiment, in the direction Z, a height of the buffer layer 160d is approximately equal to a height of the first heat-conducting assembly 140a, that is, the buffer layer 160d completely covers a side surface of the first heat-conducting assembly 140a, so that the electronic device 100d has good reliability, but the disclosure is not limited thereto.

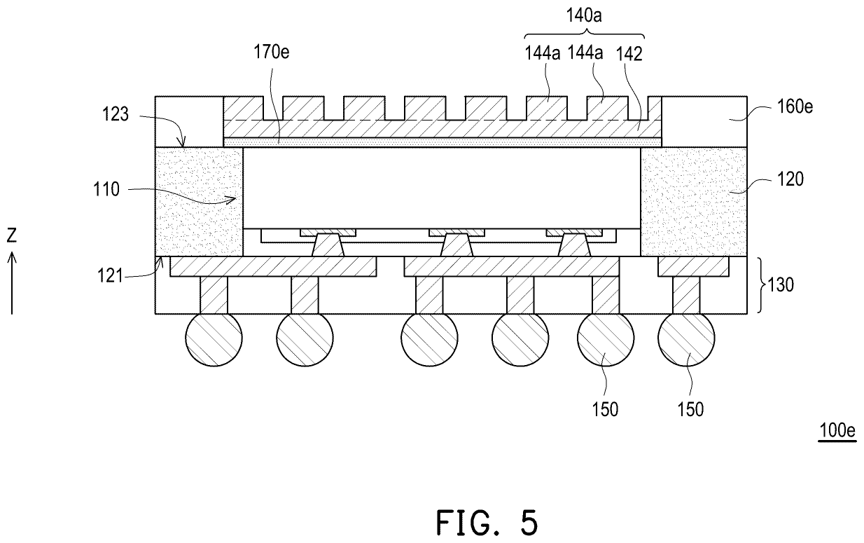

Referring to FIG. 1A and FIG. 5 at the same time, an electronic device 100e of the embodiment is similar to the electronic device 100a of FIG. 1A, and a difference therebetween is that in the embodiment, the electronic device 100e further includes a third heat-conducting assembly 170e disposed between the first portion 142 of the first heat-conducting assembly 140a and the electronic unit 110. In addition, the electronic device 100e further includes a buffer layer 160e disposed on the second side 123 of the encapsulation layer 120 and surrounding the first heat-conducting assembly 140a and the third heat-conducting assembly 170e. In direction Z, a height of the buffer layer 160e is approximately equal to a height of the first heat-conducting assembly 140a plus a height of the third heat-conducting assembly 170e, that is, the buffer layer 160d completely covers a side surface of the first heat-conducting assembly 140a and a side surface of the third heat-conducting assembly 170e, but the disclosure is not limited thereto. In an embodiment, a material of the buffer layer 160e is, for example, an organic material or an inorganic material, but the disclosure is not limited thereto. In an embodiment, the third heat-conducting assembly 170e is, for example, a thermal interface material (TIM), but the disclosure is not limited thereto.

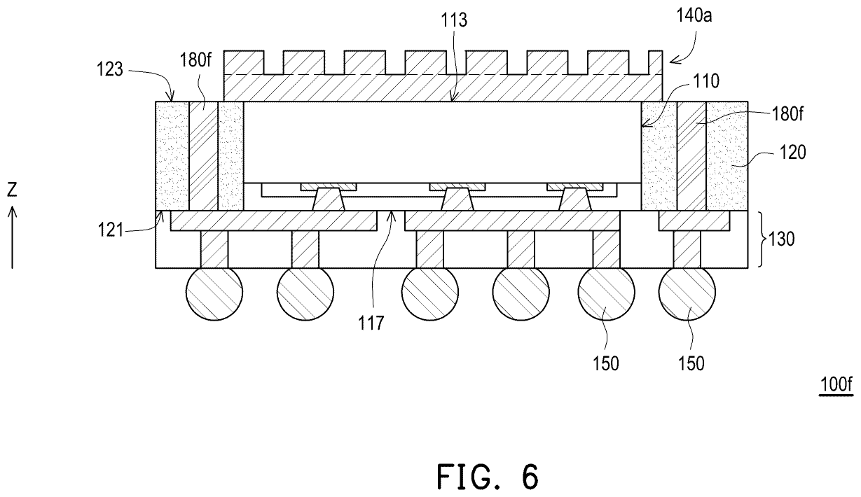

Referring to FIG. 1A and FIG. 6 at the same time, an electronic device 100f of the embodiment is similar to the electronic device 100a of FIG. 1A, and a difference therebetween is that in the embodiment, the electronic device 100f further includes a second heat-conducting assembly 180f, which is disposed adjacent to the electronic unit 110, and the encapsulation layer 120 surrounds the second heat-conducting assembly 180f. In the embodiment, the second heat-conducting assembly 180f surrounds the electronic unit 110, and the encapsulation layer 120 covers a side surface of the electronic unit 110 and a side surface of the second heat-conducting assembly 180f, where one end of the second heat-conducting assembly 180f directly contacts the circuit structure 130, and the other end of the second heat-conducting assembly 180f is exposed outside the second side 123 of the encapsulation layer 120. In other words, the heat generated by the electronic unit 110 may be directly transferred to the outside through the first heat-conducting assembly 140a disposed on the back surface 113 thereof, and may also be transferred to the outside through the circuit structure 130 disposed on the active surface 117 thereof and then through the second heat-conducting assembly 180f, thereby improving the heat dissipation effect and making the electronic device 100f to have better heat dissipation efficiency. In an embodiment, a thermal conductivity of the second heat-conducting assembly 180f is, for example, between 100 W/mK and 2000 W/mK, or between 150 W/mK and 350 W/mK, but the disclosure is not limited thereto. A material of the second heat-conducting assembly 180f may include metal, graphene, a silicon-containing material, a carbon-containing material, a semiconductor material or other suitable materials.

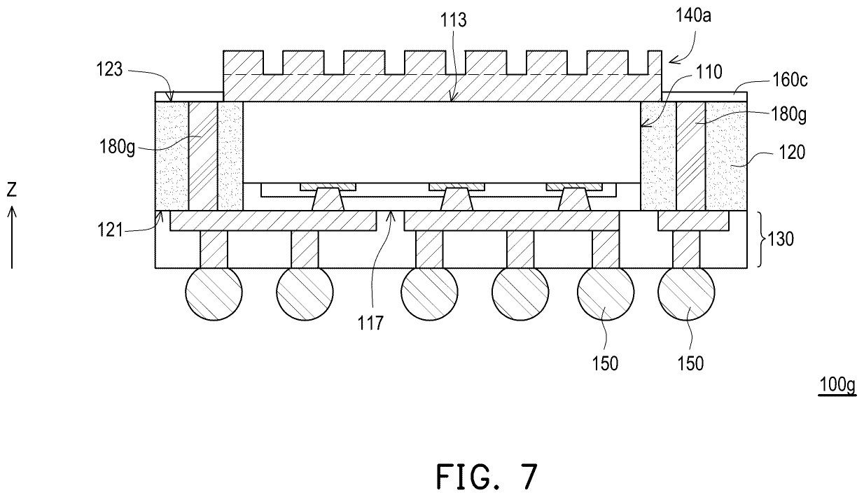

Referring to FIG. 3 and FIG. 7 at the same time, an electronic device 100g of the embodiment is similar to the electronic device 100c of FIG. 3, and a difference therebetween is that in the embodiment, the electronic device 100g further includes a second heat-conducting assembly 180g, which is disposed adjacent to the electronic unit 110, and the encapsulation layer 120 surrounds the second heat-conducting assembly 180g. In the embodiment, the second heat-conducting assembly 180g surrounds the electronic unit 110, and the encapsulation layer 120 covers a side surface of the electronic unit 110 and a side surface of the second heat-conducting assembly 180g, where one end of the second heat-conducting assembly 180g directly contacts the circuit structure 130, and the other end of the second heat-conducting assembly 180g directly contacts the buffer layer 160c. In other words, the heat generated by the electronic unit 110 may be directly transferred to the outside through the first heat-conducting assembly 140a disposed on the back surface 113 thereof, and may also be transferred to the outside through the circuit structure 130 disposed on the active surface 117 thereof and then through the second heat-conducting assembly 180g, thereby improving the heat dissipation effect and making the electronic device 100g to have better heat dissipation efficiency. In an embodiment, a thermal conductivity of the second heat-conducting assembly 180g is, for example, between 100 W/mK and 500 W/mK, or between 150 W/mK and 350 W/mK, but the disclosure is not limited thereto.

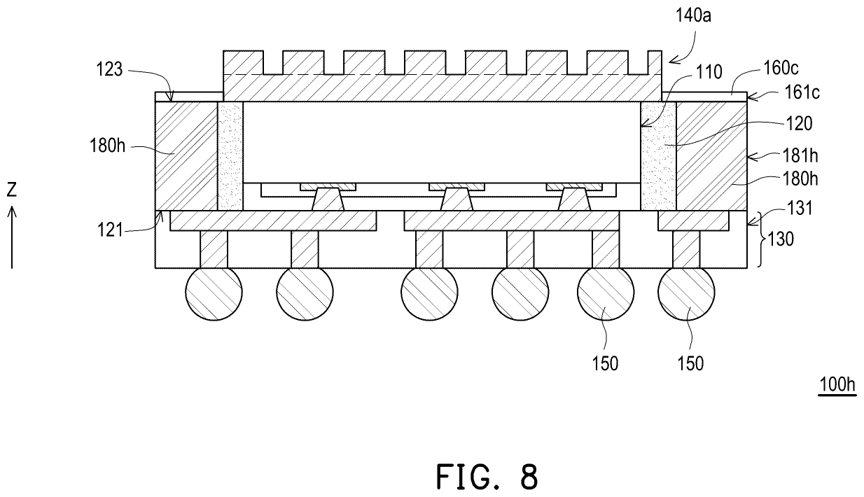

Referring to FIG. 7 and FIG. 8 at the same time, an electronic device 100h of the embodiment is similar to the electronic device 100g of FIG. 7, and a difference therebetween is that in the embodiment, a side surface 161c of the buffer layer 160c, a side surface 181h of a second heat-conducting assembly 180h and a side surface 131 of the circuit structure 130 are aligned. In other words, the side surface 181h of the second heat-conducting assembly 180h is exposed outside the encapsulation layer 120, which may improve the heat dissipation effect of the electronic device 100h.

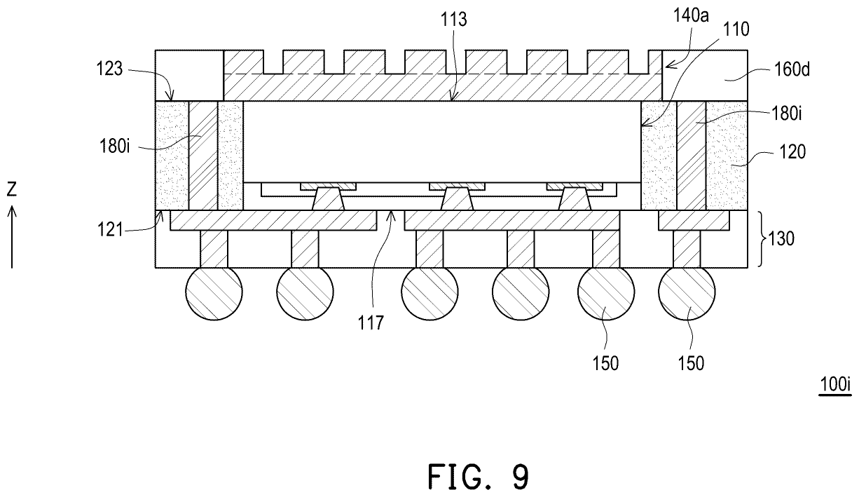

Referring to FIG. 4 and FIG. 9 at the same time, an electronic device 100i of the embodiment is similar to the electronic device 100d of FIG. 4, and a difference therebetween is that in the embodiment, the electronic device 100i further includes a second heat-conducting assembly 180i, which is disposed adjacent to the electronic unit 110, and the encapsulation layer 120 surrounds the second heat-conducting assembly 180i. In the embodiment, the second heat-conducting assembly 180i surrounds the electronic unit 110, and the encapsulation layer 120 covers a side surface of the electronic unit 110 and a side surface of the second heat-conducting assembly 180i, where one end of the second heat-conducting assembly 180i directly contacts the circuit structure 130, and the other end of the second heat-conducting assembly 180i directly contacts the buffer layer 160d. In other words, the heat generated by the electronic unit 110 may be directly transferred to the outside through the first heat-conducting assembly 140a disposed on the back surface 113 thereof, and may also be transferred to the outside through the circuit structure 130 disposed on the active surface 117 thereof and then through the second heat-conducting assembly 180i, thereby improving the heat dissipation effect and making the electronic device 100i to have better heat dissipation efficiency. In an embodiment, the thermal conductivity of the second heat-conducting assembly 180i is, for example, between 100 W/mK and 500 W/mK, or between 150 W/mK and 350 W/mK, but the disclosure is not limited thereto.

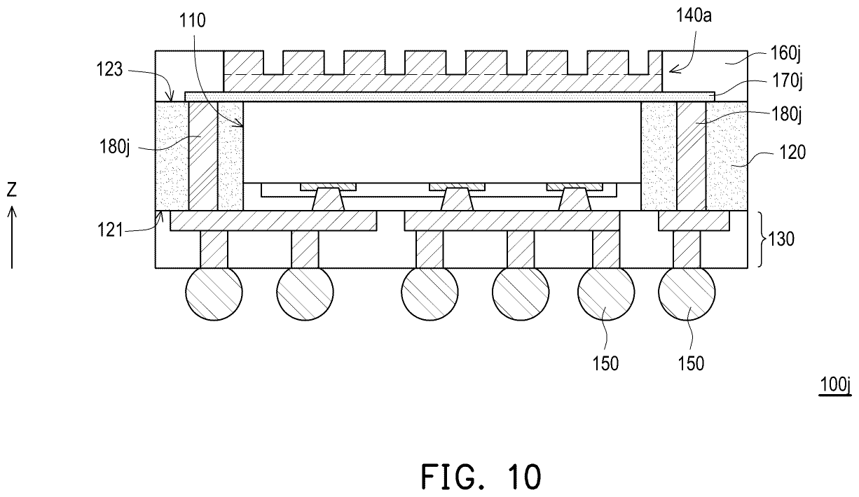

Referring to FIG. 9 and FIG. 10 at the same time, an electronic device 100j of the embodiment is similar to the electronic device 100i of FIG. 9, and a difference therebetween is that in the embodiment, the electronic device 100j further includes a third heat-conducting assembly 170j, which is disposed between the first heat-conducting assembly 140a and the electronic unit 110 and extends to the second heat-conducting assembly 180j. One end of the second heat-conducting assembly 180j directly contacts the circuit structure 130, and the other end of the second heat-conducting assembly 180j directly contacts the third heat-conducting assembly 170j. The buffer layer 160j is disposed on the second side 123 of the encapsulation layer 120 and surrounds the first heat-conducting assembly 140a and the third heat-conducting assembly 170j. In the embodiment, the buffer layer 160j directly contacts the second side 123 of the encapsulation layer 120 and a side surface of the first heat-conducting assembly 140a and a side surface and a part of an upper surface of the buffer layer 160j.

In some embodiments, the third heat-conducting assembly 170j may include a heat-conducting filler (for example, divinylbenzene cross-linked polymer, zinc oxide, aluminum oxide, beryllium oxide, silicon dioxide, boron nitride, aluminum nitride, aluminum, copper, silver, indium, similar materials or combinations thereof) and/or a polymer (for example, acetal, cellulose, acetate, polyethylene, polystyrene, acrylic acid, ethylene, nylon, polyolefin, polyester, silicone, paraffin, similar materials or combinations thereof). In some embodiments, thermal conductivity of the third heat-conducting assembly 170j is 0.5 W/mK to about 100 W/mK. In some embodiments, the thermal conductivity of the third heat-conducting assembly 170j is 0.5 W/mK to about 5 W/mK, and in some embodiments, the thermal conductivity of the third heat-conducting assembly 170j is 5 W/mK to about 10 W/mK, but the disclosure is not limited thereto.

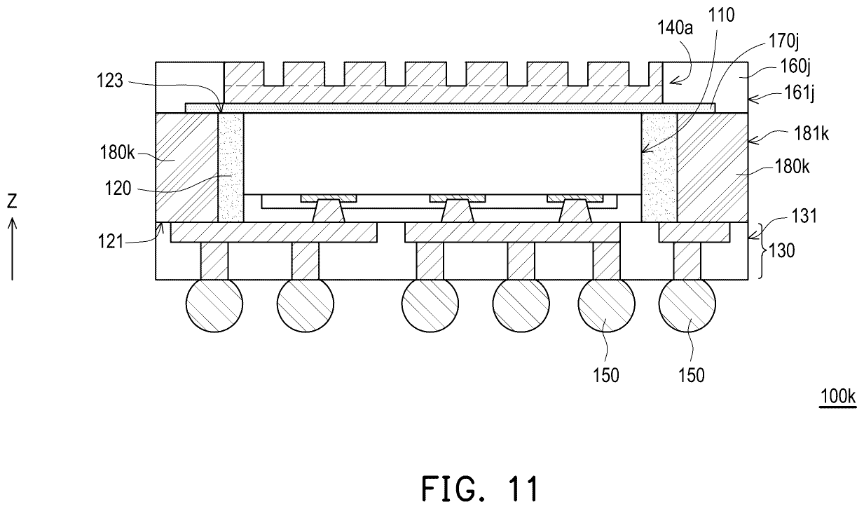

Referring to FIG. 10 and FIG. 11 at the same time, an electronic device 100k of the embodiment is similar to the electronic device 100j of FIG. 10, and a difference therebetween is that in the embodiment, a side surface 161j of the buffer layer 160j, a side surface 181k of a second heat-conducting assembly 180k and a side surface 131 of the circuit structure 130 are aligned. In other words, the side surface 181k of the second heat-conducting assembly 180k is exposed outside the encapsulation layer 120, thereby improving the heat dissipation effect of the electronic device 100h.

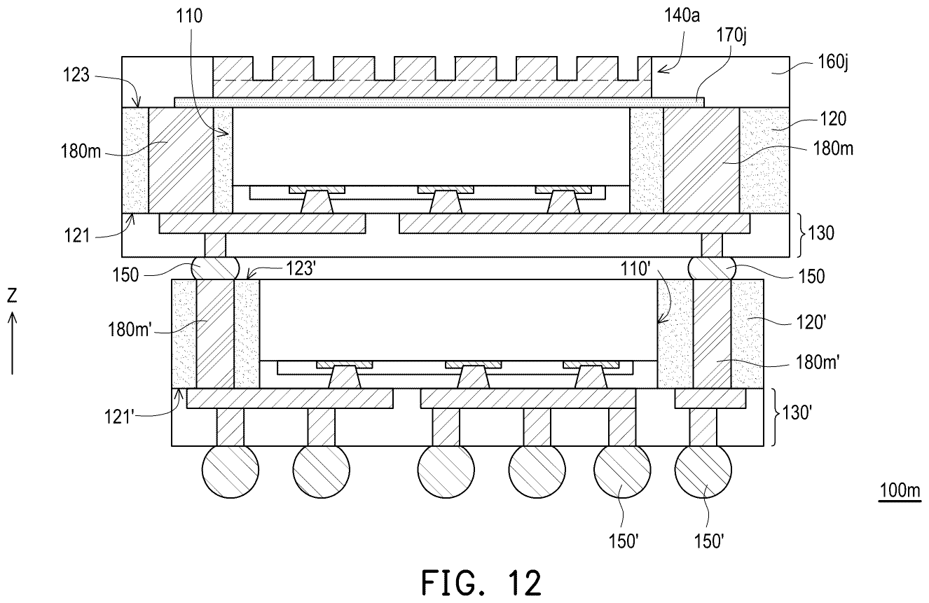

Referring to FIG. 11 and FIG. 12 at the same time, an electronic device 100m of the embodiment is similar to the electronic device 100k of FIG. 11, and a difference therebetween is that in the embodiment, a second heat-conducting assembly 180m surrounds the electronic unit 110, and the encapsulation layer 120 covers the a side surface of the electronic unit 110 and a side surface of the second heat-conducting assembly 180m. Furthermore, in the embodiment, the electronic device 100m further includes an electronic unit 110′, an encapsulation layer 120′, a circuit structure 130′, a connecting member 150′ and a second heat-conducting assembly 180m′. The encapsulation layer 120′ surrounds the electronic unit 110′ and has a first side 121′ and a second side 123′ opposite to each other. The circuit structure 130′ is disposed on the first side 121′ of the encapsulation layer 120′ and is electrically connected to the electronic unit 110′. The second heat-conducting assembly 180m′ is disposed adjacent to the electronic unit 110′, and the encapsulation layer 120′ surrounds the second heat-conducting assembly 180m′. The second heat-conducting assembly 180m′ surrounds the electronic unit 110′, and the encapsulation layer 120′ covers a side surface of the electronic unit 110′ and a side surface of the second heat-conducting assembly 180m′. One end of the second heat-conducting assembly 180m′ directly contacts the circuit structure 130′, while the other end of the second heat-conducting assembly 180m′ is exposed outside the second side 123′ of the encapsulation layer 120′, and the connecting member 150 is directly connected to the other end of the second heat-conducting assembly 180m′. In brief, the electronic device 100m of the embodiment is composed of the electronic unit 110 and electronic unit 110′ vertically stacked in the direction Z, where an appropriately sized first heat conducting assembly 140a is configured by calculating a ratio of an area of the electronic unit 110 or the electronic unit 110′ having a larger area to an area of the first heat-conducting assembly 140a, so that the electronic device 100m of the embodiment may have a better heat dissipation effect.

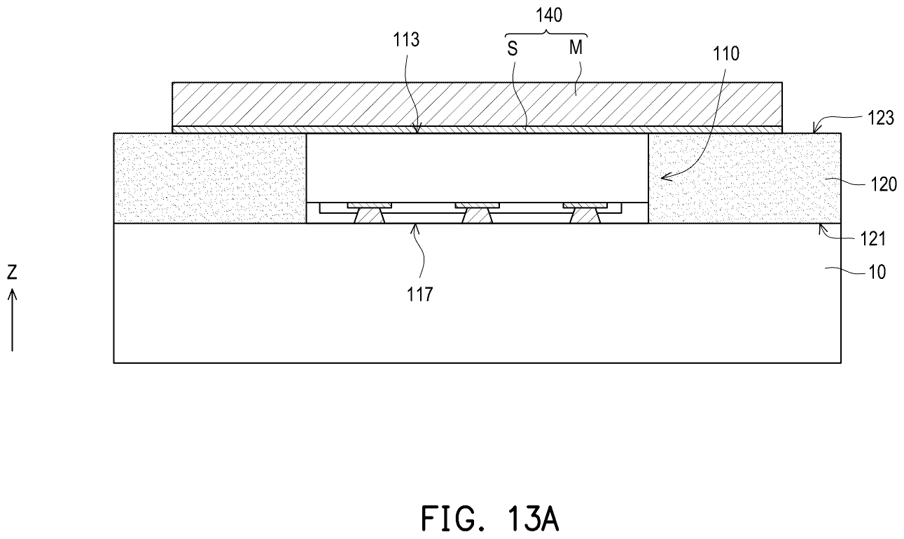

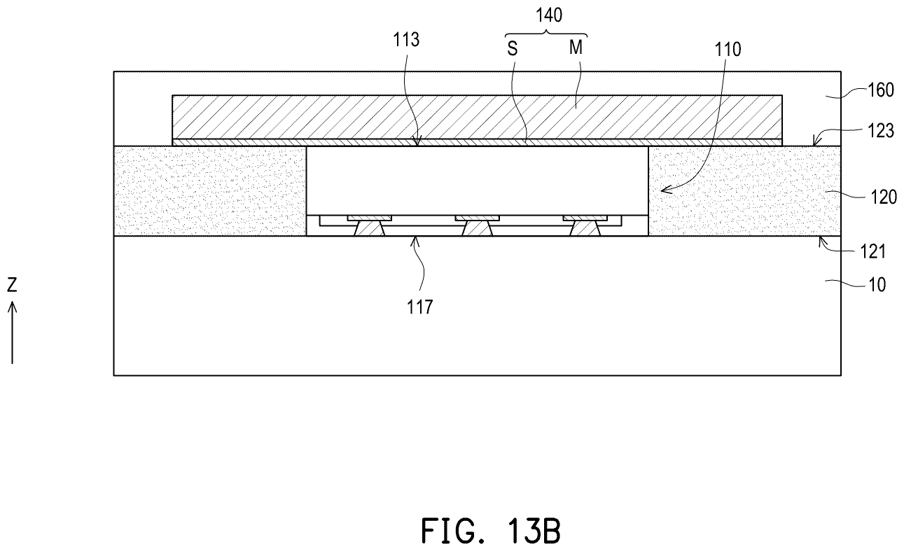

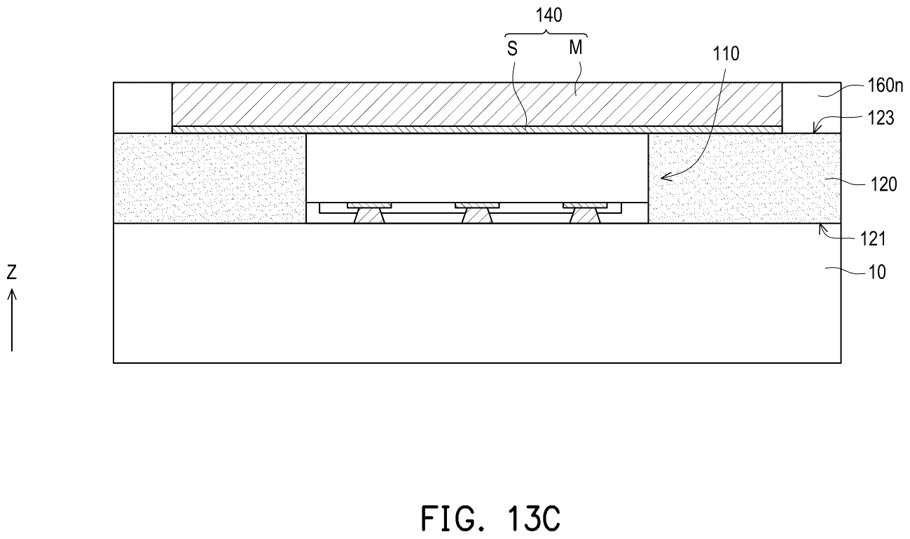

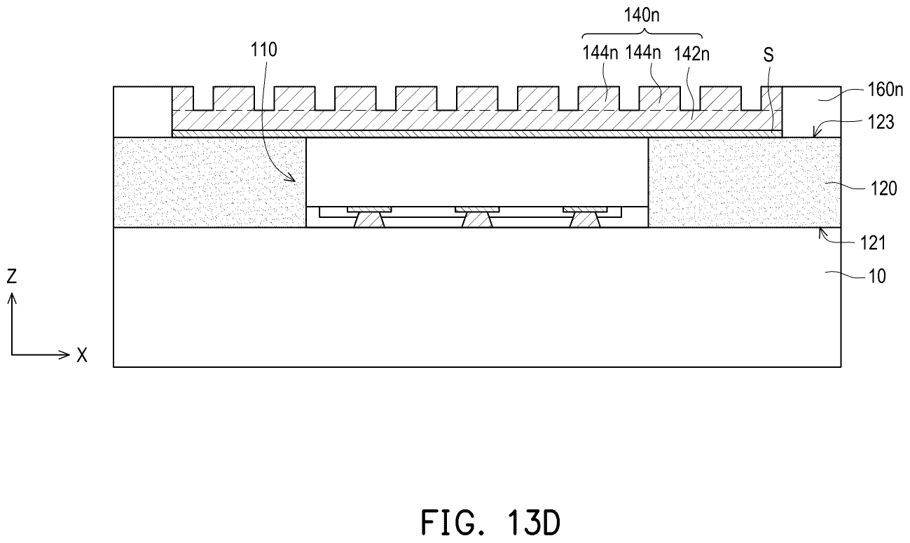

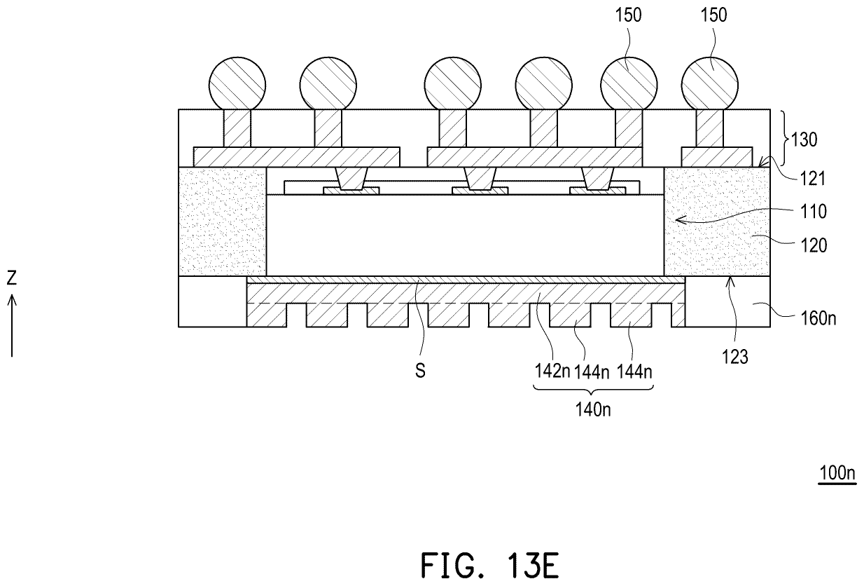

FIG. 13A to FIG. 13E are schematic cross-sectional views of a method for manufacturing an electronic device according to an embodiment of the disclosure. Referring to FIG. 13A, regarding the method for manufacturing an electronic device according to the embodiment, first, the electronic unit 110 is provided on a carrier 10, where the electronic unit 110 is disposed on the carrier 10 with the active surface 117 facing down. In an embodiment, the carrier 10 may be a glass substrate, a printed circuit board, a glass-fiber (FR4) substrate, a steel substrate or other suitable substrates, which is not limited by the disclosure. In another embodiment, the electronic unit 110 is disposed on the carrier 10 with the active surface 117 facing up, which is not limited by the disclosure.

Then, referring to FIG. 13A again, an encapsulation material layer is formed on the carrier 10 to cover the electronic unit 110. Here, the encapsulation material layer completely covers the electronic unit 110. Then, a part of the encapsulation material layer is removed by grinding to expose the back surface 113 of the electronic unit 110, thereby forming the encapsulation layer 120 surrounding the electronic unit 110. The encapsulation layer 120 has the first side 121 and the second side 123 opposite to each other, and the first side 121 is located on the carrier 10.

Then, referring to FIG. 13A again, where the first heat-conducting assembly 140a is provided on the second side 123 of the encapsulation layer 120. First, a seed material layer is formed on the back surface 113 of the electronic unit 110 and the second side 123 of the encapsulation layer 120. In an embodiment, the seed material layer is a metal layer, which may be a single layer or a composite layer of multiple sub-layers composed of different materials. In an embodiment, the seed material layer may include a titanium layer and a copper layer above the titanium layer, and the seed material layer may be formed by using, for example, PVD or a similar method. Then, a patterned photoresist layer is formed on the seed material layer, where the patterned photoresist layer exposes a part of the seed material layer. Then, the patterned photoresist layer is used as a plating mask to electroplate a metal material on the seed material layer exposed by the patterned photoresist layer. Then, the patterned photoresist layer and the seed material layer thereunder are removed to form a metal layer M and a seed layer S thereunder to define a heat-conducting assembly 140.

Then, referring to FIG. 13B, a buffer material layer 160 is formed on the second side 123 of the encapsulation layer 120, where the buffer material layer 160 completely covers the heat-conducting assembly 140.

Then, referring to FIG. 13C, a part of the buffer material layer 160 is removed to form a buffer layer 160n exposing the heat-conducting assembly 140.

Then, referring to FIG. 13D, the heat-conducting assembly 140 is patterned by, for example, an etching process or a laser cutting process, to form a first heat-conducting assembly 140n. The first heat-conducting assembly 140n includes a first portion 142n and a plurality of second portions 144n, where the first portion 142n is located between the seed layer S and the plurality of second portions 144n, and the plurality of second portions 144n are connected to the first portion 142n. In an embodiment, the first portion 142n may, for example, extend along the direction X, and the second portions 144n are separated from each other and may, for example, extend along the direction Z. Thus, the first heat-conducting assembly 140n is provided on the second side 123 of the encapsulation layer 120.

Finally, referring to FIG. 13D and FIG. 13E, the carrier 10 is removed to expose the first side 121 of the encapsulation layer 120. Then, the circuit structure 130 is formed on the first side 121 of the encapsulation layer 120, where the circuit structure 130 is electrically connected to the electronic unit 110. In this way, manufacturing of the electronic device 100n is completed.

It should be noted that the aforementioned first heat-conducting assembly 140n is provided by electroplating, but the disclosure is not limited thereto. In other embodiments, other methods may be used, for example, a pre-formed first heat-conducting assembly is directly provided on the back surface of the electronic unit.

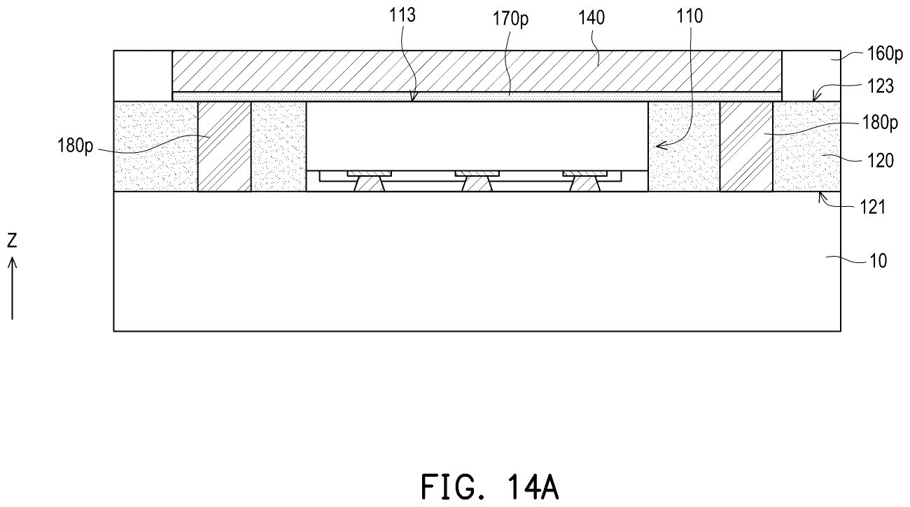

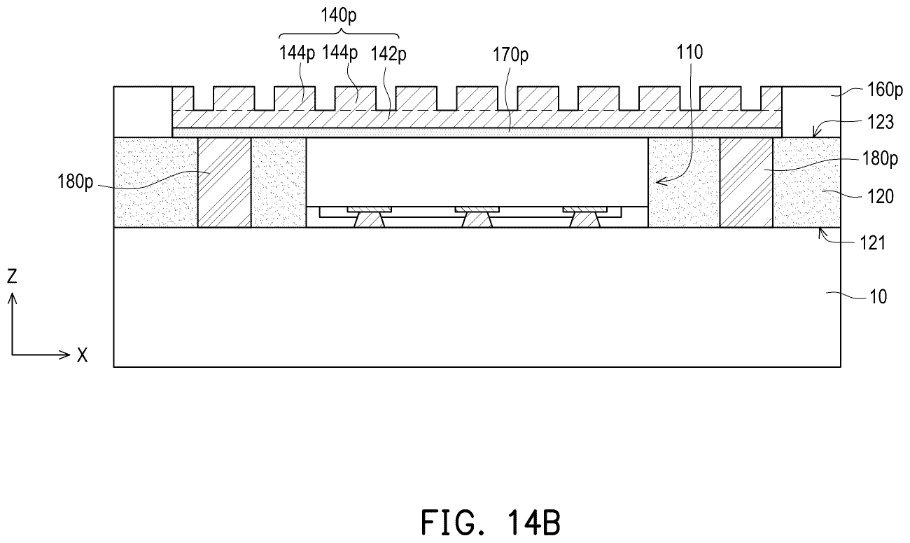

FIG. 14A to FIG. 14B are schematic cross-sectional views of partial steps of a method for manufacturing an electronic device according to another embodiment of the disclosure. Referring to FIG. 13A and FIG. 14A at the same time, the method for manufacturing an electronic device according to the embodiment is similar to the method for manufacturing an electronic device described above, and a difference therebetween is that in the embodiment, before forming the encapsulation layer 120 on the carrier 10, a second heat-conducting assembly 180p is formed on the carrier 10 to be adjacent to the electronic unit 110. The second heat-conducting assembly 180p surrounds the electronic unit 110, and the encapsulation layer 120 covers the surrounding surfaces of the electronic unit 110 and the second heat-conducting assembly 180p. Then, a third heat-conducting assembly 170p is formed on the back surface 113 of the electronic unit 110 and extends to cover one end of the second heat-conducting assembly 180p. In an embodiment, the third heat-conducting assembly 170p is, for example, a thermal interface material (TIM), but the disclosure is not limited thereto.

Then, referring to FIG. 14A again, the heat-conducting assembly 140 is provided on the third heat-conducting assembly 170p, where the heat-conducting assembly 140 is fixed on the second side 123 of the encapsulation layer 120 through the third heat-conducting assembly 170p. In other words, the heat-conducting assembly 140 is an externally attached heat-conducting assembly. Then, a buffer material layer is formed on the second side 123 of the encapsulation layer 120, where the buffer material layer completely covers the heat-conducting assembly 140. Then, a part of the buffer material layer is removed to form a buffer layer 160p exposing the heat-conducting assembly 140.

Then, referring to FIG. 14B, the heat-conducting assembly 140 is patterned, such as by etching or laser cutting, to form the first heat-conducting assembly 140p. The first heat-conducting assembly 140p includes a first portion 142p and a plurality of second portions 144p, where the first portion 142p is located between the third heat-conducting assembly 170p and the plurality of second portions 144p, and the plurality of second portions 144p are connected to the first portion 142p. In an embodiment, the first portion 142p may, for example, extend along the direction X, and the second portions 144p are separated from each other and may, for example, extend along the direction Z. In this way, the first heat-conducting assembly 140p is provided on the second side 123 of the encapsulation layer 120.

In summary, in the embodiments of the disclosure, the ratio of the first area of the first heat-conducting assembly to the second area of the electronic unit is greater than or equal to 1 and less than 9.8, thereby improving the heat dissipation effect of the electronic device of the disclosure, and accordingly reducing or preventing warpage of the electronic device.

Finally, it should be noted that the above embodiments are only used to illustrate the technical solutions of the disclosure, rather than to limit it. Although the disclosure has been described in detail with reference to the aforementioned embodiments, those skilled in the art should understand that they may still modify the technical solutions described in the aforementioned embodiments, or replace some or all of the technical features therein by equivalents. However, these modifications or replacements do not cause the essence of the corresponding technical solutions to deviate from the scope of the technical solutions of the embodiments of the disclosure.

What is claimed is:

1. An electronic device, comprising:
an electronic unit;
an encapsulation layer, surrounding the electronic unit, and having a first side and a second side opposite to each other;
a circuit structure, disposed on the first side of the encapsulation layer, and electrically connected to the electronic unit; and
a first heat-conducting assembly, disposed on the second side of the encapsulation layer, wherein viewing in a top view, the first heat-conducting assembly has a first area, the electronic unit has a second area, and a ratio of the first area to the second area is greater than or equal to 1 and less than 9.8.

2. The electronic device as claimed in claim 1, further comprising:
a second heat-conducting assembly, disposed adjacent to the electronic unit, and the encapsulation layer surrounding the second heat-conducting assembly.

3. The electronic device as claimed in claim 2, wherein a material of the second heat-conducting assembly comprises metal, graphene, a silicon-containing material, a carbon-containing material or a semiconductor material.

4. The electronic device as claimed in claim 1, further comprising:
a third heat-conducting assembly, disposed between the first heat-conducting assembly and the electronic unit.

5. The electronic device as claimed in claim 4, wherein the third heat-conducting assembly comprises a thermal interface material or contains a heat-conducting filler and/or a polymer.

6. The electronic device as claimed in claim 1, wherein the electronic unit comprises a chip, and viewing in a top view, the chip has a third area, and a ratio of the first area to the third area is greater than or equal to 1 and less than 9.8.

7. The electronic device as claimed in claim 1, further comprising:
a buffer layer, disposed on the second side of the encapsulation layer, and surrounding the first heat-conducting assembly.

8. The electronic device as claimed in claim 7, wherein the buffer layer exposes a part of a side surface of the first heat-conducting assembly.

9. The electronic device as claimed in claim 7, wherein the buffer layer completely covers a side surface of the first heat-conducting assembly.

10. The electronic device as claimed in claim 7, wherein a ratio of an area of the buffer layer to an area of the encapsulation layer is between 0.1 and 0.9.

11. The electronic device as claimed in claim 7, wherein a material of the buffer layer comprises an organic material or an inorganic material.

12. The electronic device as claimed in claim 1, further comprising:
a connecting member, disposed on the circuit structure, and electrically connected to the circuit structure.

13. The electronic device as claimed in claim 1, wherein the first heat-conducting assembly comprises a first portion and a plurality of second portions, the first portion is located between the electronic unit and the plurality of second portions, and the plurality of second portions are connected to the first portion.

14. The electronic device as claimed in claim 13, wherein the first portion has a first height, the second portion has a second height, and the first height is greater than the second height.

15. The electronic device as claimed in claim 13, wherein the first portion has a surface, the surface has a first surface area, the plurality of second portions have a second surface area, and a ratio of the second surface area to the first surface area is between 1.5 and 5.

16. The electronic device as claimed in claim 13, wherein viewing in a cross-sectional view, a shape of the second portion comprises a square, a rectangle, a trapezoid, a triangle, a semicircle, an ellipse, an arc, or a combination of the above shapes.

17. The electronic device as claimed in claim 1, wherein the ratio of the first area to the second area is greater than or equal to 2 and less than 8.

18. The electronic device as claimed in claim 1, wherein a back surface of the electronic unit is aligned with the second side of the encapsulation layer.

19. A method for manufacturing an electronic device, comprising:
providing an electronic unit on a carrier;
forming an encapsulation layer is formed on the carrier, wherein the encapsulation layer surrounds the electronic unit and has a first side and a second side opposite to each other, and the first side is located on the carrier;
providing a first heat-conducting assembly on the second side of the encapsulation layer;
removing the carrier to expose the first side of the encapsulation layer; and
forming a circuit structure on the first side of the encapsulation layer, wherein the circuit structure is electrically connected to the electronic unit, and viewing in a top view, the first heat-conducting assembly has a first area, the electronic unit has a second area, and a ratio of the first area to the second area is greater than or equal to 1 and less than 9.8.

20. The method for manufacturing the electronic device as claimed in claim 19, further comprising:
forming a second heat-conducting assembly on the carrier to be adjacent to the electronic unit before forming the encapsulation layer on the carrier.
